(19) United States
(12) Patent Application Publication
(10) Pub. No.: US 2009/0194857 A1
(43) Pub. Date: Aug. 6, 2009

(54) Thin Compact Semiconductor Die Packages Suitable for Smart-Power Modules, Methods of Making the Same, and Systems Using the Same

(76) Inventors: Yong Liu, Scarborough, ME (US); Yumin Liu, Suzhou (CN); Hua Yang, Jiang Su Province (CN); Tiburcio A. Maldo, Suzhou (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 12/024,847

(22) Filed: Feb. 1, 2008

(51) Int. Cl. H01L 23/495; H01L 21/00

(52) U.S. Cl. 257/676; 438/119; 257/E23.031; 257/E21.001

(57) ABSTRACT

Disclosed are semiconductor die packages, methods of making them, and systems incorporating them. An exemplary package comprises a first substrate, a second substrate, a semiconductor die disposed between the first and second substrates, and an electrically conductive member disposed between the first and second substrates. The semiconductor die has a conductive region at its first surface that is electrically coupled to a first conductive region of the first substrate, and another conductive region at its second surface that is electrically coupled to a first conductive region of the second substrate. The conductive member is electrically coupled between the first conductive region of the second substrate and a second electrically conductive region of the first substrate. This configuration enables terminals on both surfaces of the semiconductor die to be coupled to the first substrate.

### CROSS-REFERENCES TO RELATED APPLICATIONS

NOT APPLICABLE

### BACKGROUND OF THE INVENTION

Current smart power module (SPM) products are focusing on high power applications, such as motor drivers for air conditioners, washing machines, refrigerators, other household appliances, and the like. Such modules typically comprise one or more semiconductor power devices and one or more control chips or driver chips packaged together in a dual-in-line pin package with the components mounted on a leadframe and electrically interconnected with wire bonds. Smart power modules for the aforementioned applications must be small and inexpensive on the one hand, but must have high reliability on the other hand. These requirements are conflicting, and, to date, it has been difficult to achieve all of the requirements simultaneously.

### BRIEF SUMMARY OF THE INVENTION

As part of making their invention, the inventors have discovered that a SPM package having a smaller size and a land-grid array or ball-grid array connector structure, instead of dual-in-line pin connector structure, can enable appliance manufacturers to reduce their manufacturing costs by using smaller system boards and less expensive board assembling processes. In addition, the inventors have discovered that the relatively large size of connection pads of semiconductor dice used in SPM's enables new types of package construction that reduce manufacturing time and cost. Specifically, the dice may be assembled onto one or both assembly surfaces of two substrates using pick-and-place equipment, and the two substrate assembly surfaces may then be joined together using assembly equipment that does not require a high degree of alignment precision. Such assembly equipment may, for example, comprise a simple jig that couples to one of the substrates, and provides an alignment aperture or alignment guides for the other substrate. The semiconductor dice are assembled so that conductive regions on their surfaces face corresponding conductive regions on the substrates, and are electrically coupled thereto. The inventors have further discovered that electrical connections between the substrates may be provided by small conductive members (e.g., posts) disposed between the substrates and electrically coupled to conductive regions of the substrates, and with these conductive members having thicknesses near those of the semiconductor dice. The inventors have further discovered that the use of two substrates enables the electrical interconnections to be made more efficiently, and enables the dice to be placed more closely together, leading to a thinner and more compact package. Packages according to the present invention can be more than 65% smaller in size and thickness than existing DIP packages having the same functionality (that is, they are less than one-third the size and thickness of existing packages). In addition, the inventors have discovered preferred embodiments where one of the substrates is constructed to comprise a direct-bond-copper substrate or an insulated metal substrate and to provide a coupling surface for a heat sink, thereby enabling efficient cooling of the dice, and even more compact packages.

Accordingly, a first general embodiment of the invention is directed to a semiconductor die package comprising: a first substrate, a second substrate, a semiconductor die disposed between the first and second substrates, and an electrically conductive member disposed between the first and second substrates. The semiconductor die has a conductive region at its first surface that is electrically coupled to a first conductive region of the first substrate, and another conductive region at its second surface that is electrically coupled to a first conductive region of the second substrate. The conductive member is electrically coupled between the first conductive region of the second substrate and a second electrically conductive region of the first substrate. This configuration enables terminals on both surfaces of the semiconductor die to be coupled to the first substrate, and further enables the first substrate to be configured to provide electrical interconnections to the die, and the second substrate to be configured to conduct heat away from the semiconductor die. In further preferred embodiments following this first general embodiment, the semiconductor die comprises a power transistor device, and additional power transistor dice are disposed between first and second substrates in a manner similar to the first semiconductor die. In yet further preferred embodiments following these embodiments, one or more semiconductor die having control circuitry and/or driver circuitry are disposed on the first substrate and electrically interconnected with the power semiconductor dice by way of electrical traces formed in and/or on the first substrate. In still further preferred embodiments, electrical connections to the package are provided by a land-grid array or ball-grid array disposed on the second surface of the first substrate.

A second general embodiment of the present invention is directed to a method of forming a semiconductor die package comprising: assembling a first semiconductor die onto one of a first substrate and a second substrate, assembling a first conductive member onto one of the first and second substrates, and assembling the first surfaces of the first and second substrates together with the first semiconductor die and the first conductive member disposed between the substrates. Each substrate has a first surface and a second surface, with the semiconductor die being assembled onto the first surface of one of the substrates, and the conductive member being assembled onto the first surface of one of the substrates. The semiconductor die and conductive member may be assembled onto the same substrate or different substrates, and may be assembled onto the substrate(s) in any time sequence, thereby enabling the manufacturing process to be carried out in the most efficient manner depending upon the capabilities of the available assembly equipment. The semiconductor die is preferably assembled with electrically conductive regions at each of its surfaces being electrically coupled to corresponding electrically conductive regions of the substrates. Similarly, the conductive member is preferably assembled with each of its electrically conductive regions being electrically coupled to corresponding electrically conductive regions of the substrates. In preferred embodiments, an electrically conductive adhesive is disposed between these conductive regions/surfaces to make the electrical couplings therebetween. In yet further preferred embodiments, the electrically conductive adhesive comprises solder material, and the solder material is reflowed after the first and second substrates have been assembled together.

Another general embodiment of the invention is directed to a system, such as an electronic device that comprises a semiconductor die package according to the invention.

Accordingly, it is an objective of the present invention to provide thinner and/or more compact packages for housing and interconnecting multiple semiconductor dice.

It is a further objective of the present invention to provide less expensive packages for housing and interconnecting multiple semiconductor dice.

These and other embodiments of the invention are described in detail in the Detailed Description with reference to the Figures. In the Figures, like numerals may reference like elements and descriptions of some elements may not be repeated.

### BRIEF DESCRIPTION OF THE DRAWINGS

FIG. 1 shows an exploded perspective view of a first exemplary semiconductor die package, prior to assembling of the first and second substrates, according to the present invention.

FIG. 2 shows a top perspective view of the first exemplary semiconductor die package, with the first and second substrates assembled together, according to the present invention.

FIG. 3 shows a cross-sectional view of the first exemplary semiconductor die package, with the first and second substrates assembled together, according to the present invention.

FIG. 4 shows a bottom perspective view of the first exemplary semiconductor die package, with the first and second substrates assembled together, according to the present invention.

FIG. 5 shows a top perspective view of the first exemplary semiconductor die package, after a molding material has been disposed about the sides of the first and second substrates, according to the present invention.

FIG. 6 shows a circuit schematic of electrical circuitry that may be housed within the first exemplary semiconductor die package according to the present invention.

FIG. 7 shows a top perspective view of the first exemplary system that incorporates an exemplary semiconductor die package according to the present invention.

FIG. 8 shows a cross-sectional view of a second exemplary semiconductor die package, with the first and second substrates assembled together, according to the present invention.

FIGS. 9-11 illustrate the metal trace layers and vias on the substrate of an exemplary implementation of a first substrate according to the present invention.

### DETAILED DESCRIPTION OF THE INVENTION

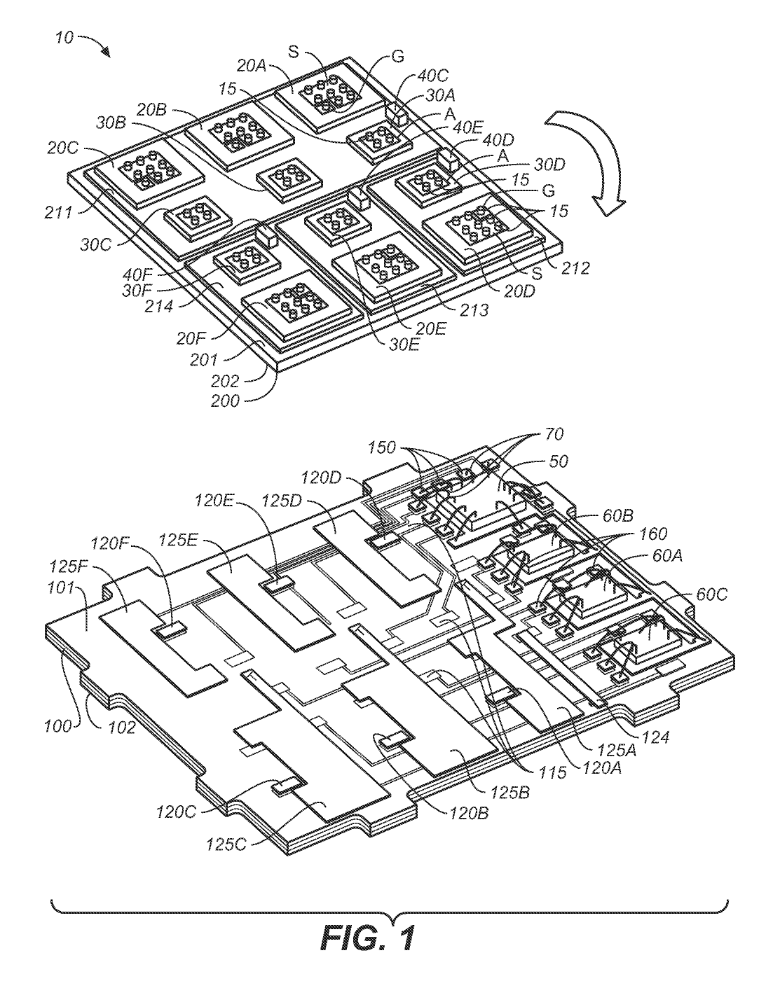

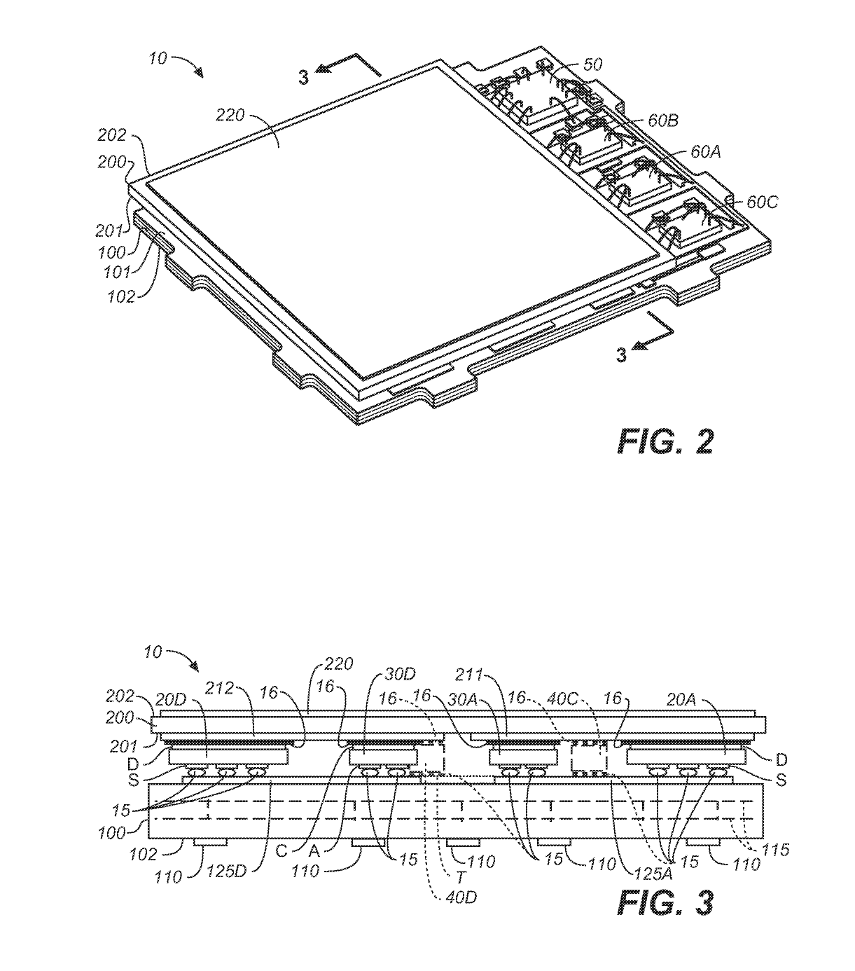

FIG. 1 shows an exploded perspective view of an exemplary multiple semiconductor die package 10 according to the present invention. Package 10 comprises a first substrate 100, a second substrate 200, a plurality of transistor semiconductor dice 20A-20F, a plurality of rectifier semiconductor dice 30A-30F, a plurality of conductive members 40C-40F, a low-side drive chip 50, a plurality of high-side drive chips 60A-60C, and a plurality of wire bonds 70. First substrate 100 has a top surface 101, a bottom surface 102, and a plurality of conductive regions 120A-120F, 124, 125A-125F, 150, 160 disposed on first surface 101. Second substrate 200 comprising a first surface 201 and a second surface 202 (shown in FIG. 2), and a plurality of conductive regions 211-214 formed on first surface 201. In the assembled form of package 10, the first surface 101 of substrate 100 and the first surface 201 of substrate 200 are assembled together (in the area of conductive regions 120A-120F, 124 and 125A-125F), with dice 20A-20F, dice 30A-30F, and conductive members 40C-40F disposed between the substrates. This assembled form is shown in FIG. 2, where the second surface 202 of substrate 200 is visible. In FIG. 2, it can be seen that substrate 200 may comprise a conductive region 220 disposed on second surface 202. As shown below in greater detail, a heat sink may be attached to conductive region 220 to aid in dissipating heat from package 10. The other reference numbers shown in FIG. 2 were described above with respect to FIG. 1. FIG. 3 shows a cross-sectional view of package 10 taken through dice 20A, 30A, 20D, and 30D, and the various features shown therein are described below.

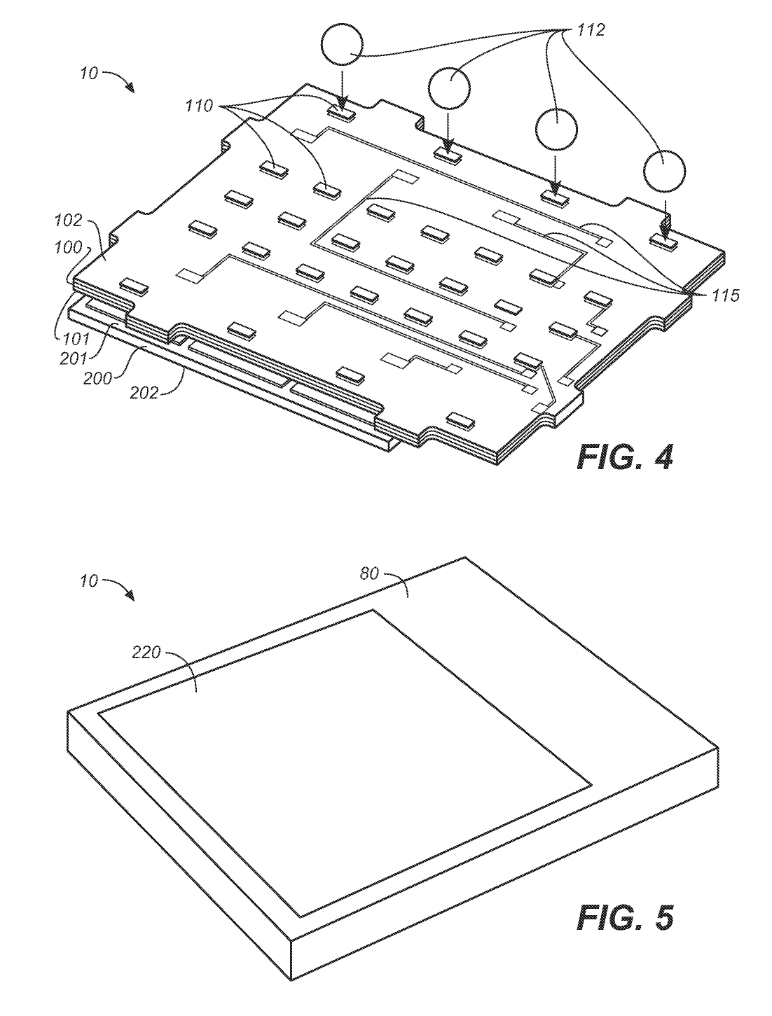

Referring briefly to FIG. 4, first substrate 100 further preferably comprises a plurality of lands 110 formed on its second surface 102 to provide external connections between package 10 and a system incorporating package 10. Lands 110 are preferably provided in a regular pattern to provide a land-grid array, and solder balls 112 may be deposited on lands 110 to further provide a ball-grid array. In addition, first substrate 100 further preferably comprises a network 115 of electrical traces and vertical connectors (e.g., vias) formed within its body to provide electrical interconnections among selected ones of conductive regions 120A-120F, 124, 125A-125F, 150, and 160, and between selected ones of these conductive regions and lands 110. The interconnections of network 115 provide the desired electrical circuit nets for an implementation of package 10. Substrate 100 may comprise a printed circuit board comprising one or more sheets of FR4 material (which is an electrically insulating material), one or more sets of vertical connectors formed through the one or more sheets, and two or more patterned metal layers disposed between the one or more sheets. Substrate 100 may also comprise a multi-layer ceramic substrate formed by laminating and then firing a plurality of ceramic green sheets having via hole and printed conductive paste patterns.

Referring back to FIGS. 1-3, second substrate 200 may comprise a direct-bonded copper (DBC) substrate, an insulated metal (IMS) substrate, or the like. An exemplary direct bonded copper substrate comprises a sheet of ceramic material, such as alumina, with a sheet of copper bonded to each surface of the ceramic sheet by a high-temperature oxidation process (the copper and substrate are heated to a controlled temperature in an atmosphere of nitrogen containing a small amount of oxygen, around 30 ppm, which forms a copper-oxygen eutectic bonding layer between each copper sheet and the oxides present in the ceramic material). An exemplary insulated metal substrate comprises a metal sheet, such as an aluminum or copper sheet, covered by a thin layer of dielectric material (typically an epoxy-based material), which in turn is covered by a copper layer. The copper layer can be patterned to provide a desired set of conductive regions.

Referring back to FIG. 1, each transistor semiconductor die 20A-20F comprises a first surface (shown in FIGS. 1 and 3), a second surface (shown in FIG. 3) opposite to its first surface, a first conductive region G and second conductive region S disposed on its first surface, and a third conductive region D (shown in FIG. 3) disposed on its second surface. For the sake of visual clarity in the figures, these components are only shown for semiconductor dice 20A and 20D. Each semiconductor die 20A-20F preferably comprises a transistor having a modulation terminal coupled to first conductive region G, a first conduction terminal coupled to second conductive region S, and a second conduction terminal coupled to third conductive region D. In an exemplary implementation, each semiconductor die 20A-20F comprises a vertical power device, preferably a power MOSFET device, having a first conduction terminal (e.g., source) at first conductive regions S, a second conduction terminal (e.g., drain) at second conductive region D, and a modulation terminal (e.g., gate) at third conductive region G. However, each semiconductor die 20A-20F may comprise other power devices, such as rectifiers, controlled rectifiers (e.g., SCRs), bipolar transistors, insulated-gate field-effect transistors, etc., and may comprise non-power devices such as digital circuits and analog circuits (e.g., power amplifiers).

Referring to FIGS. 1 and 3, the first conductive regions G of transistor dice 20A-20F are disposed to face conductive regions 120A-120F of first substrate 100, respectively, and to be electrically coupled thereto by bodies 15 of conductive adhesive, such as by the solder bodies shown on the conductive regions G. The second conductive regions S of transistor dice 20A-20F are disposed to face conductive regions 125A-125F of first substrate 100, respectively, and to be electrically coupled thereto by bodies of conductive adhesive, such as by the solder bodies 15 shown on the conductive regions S. The third conductive regions D of transistor dice 20A-20C are disposed to face conductive region 211 of second substrate 200, and to be electrically coupled thereto by respective bodies 16 of conductive adhesive, such as the solder body 16 shown in FIG. 3 for transistor die 20A. The third conductive regions D of transistor dice 20D-20F are disposed to face conductive region 212-214 of second substrate 200, and to be electrically coupled thereto by bodies of conductive adhesive, such as like the solder body 16 shown in FIG. 3 for transistor die 20A.

Each rectifier semiconductor die 30A-30F comprises a first surface (shown in FIGS. 1 and 3), a second surface opposite to its first surface (shown in FIG. 3), a first conductive region A disposed on its first surface (shown in FIGS. 1 and 3), and a second conductive region C (shown in FIG. 3) disposed on its second surface. For the sake of visual clarity in the figure, these components are only shown for semiconductor dice 30A and 30D. Each semiconductor die 30A-30F comprises a fast recovery diode having an anode terminal coupled to first conductive region A, and a cathode terminal coupled to second conductive region C. The first conductive regions A of rectifier dice 30A-30F are disposed to face conductive regions 125A-125F of first substrate 100, respectively, and to be electrically coupled thereto by bodies 15 of conductive adhesive, such as the solder bodies 15 shown on the conductive regions A. The second conductive regions C of rectifier dice 30A-30C are disposed to face conductive region 211 of second substrate 200, and to be electrically coupled thereto by bodies 16 of conductive adhesive (e.g., solder), such as the body 16 shown in FIG. 3 for rectifier die 30A. The second conductive regions C of rectifier dice 30D-30F are disposed to face conductive region 212-214 of second substrate 200, respectively, and to be electrically coupled thereto by bodies 16 of conductive adhesive (e.g., solder), such as like the solder body 16 shown in FIG. 3 for rectifier die 30A.

In this manner, the fast recovery diodes of rectifier dice 30A-30F are electrically coupled in parallel with the transistors of transistor dice 20A-20F, respectively, at the conduction terminals of the transistors. This connection configuration, which is illustrated in the circuit schematic of FIG. 6, enables reverse currents to flow through the diodes after their respective transistors turn off, thereby preventing high reverse voltages that could destroy the transistors. This configuration is especially suitable when the transistors are switching current to and from inductive loads. In some implementations of package 10, diodes are incorporated into transistor dice 20A-20F, and rectifier dice 30A-30F are not needed, and can be omitted.

Referring still to FIGS. 1 and 3, each conductive member 40C-40F comprises a solid body of conductive material, and has a first conductive region and a second conductive region. In FIG. 3, conductive members 40C and 40D are outside of the cross-section plane but are shown in dashed lines for reference. One conductive region of conductive member 40C is electrically coupled to conductive region 211 of substrate 200 by a body 16 of conductive adhesive (shown in FIG. 3), and the other conductive region of conductive member 40C is electrically coupled to conductive region 124 of substrate 100 by a body 15 of conductive adhesive (shown in FIGS. 1 and 3), which may comprise solder. (In the cross-section of FIG. 3, conductive region 124 is located behind conductive region 125A, and not visible.) This provides an electrical connection between conductive region 124 on the one hand, and the conductive regions D of transistor dice 20A-20C and the conductive regions C of rectifier dice 30A-30C on the other hand.

One conductive region of conductive member 40D is electrically coupled to conductive region 212 of substrate 200 by a body 16 of conductive adhesive (shown in FIG. 3), and the other conductive region of conductive member 40D is electrically coupled to a tail portion of conductive region 125A of first of substrate 100 by a body 15 of conductive adhesive (shown in FIGS. 1 and 3). The tail portion is marked with the letter T in FIGS. 1 and 3, and the conductive adhesive may comprise solder. (The tail portion T is outside of the cross-section plane of FIG. 3, but is shown in dashed lines for reference.) This provides an electrical connection between conductive region D of transistor die 20D and the conductive region C of rectifier die 30D on the one hand, and the conduction region S of transistor die 20A and the conduction region A of rectifier die 30A on the other hand.

In a similar manner, one conductive region of conductive member 40E is electrically coupled to conductive region 213 of substrate 200 by a body 16 of conductive adhesive (not shown), and the other conductive region of conductive member 40E is electrically coupled to a tail portion of conductive region 125B of first of substrate 100 by a body 15 of conductive adhesive (shown in FIG. 1). This provides an electrical connection between conductive region D of transistor die 20E and the conductive region C of rectifier die 30E on the one hand, and the conduction region S of transistor die 20B and the conduction region A of rectifier die 30B on the other hand.

Also in a similar manner, one conductive region of conductive member 40F is electrically coupled to conductive region 214 of substrate 200 by a body 16 of conductive adhesive (not shown), and the other conductive region of conductive member 40F is electrically coupled to a tail portion of conductive region 125C of first of substrate 100 by a body 15 of conductive adhesive (shown in FIG. 1). This provides an electrical connection between conductive region D of transistor die 20F and the conductive region C of rectifier die 30F on the one hand, and the conduction region S of transistor die 20C and the conduction region A of rectifier die 30C on the other hand.

Referring to FIG. 1, low-side drive chip 50 is attached to first surface 101 of substrate 100 and is coupled to a plurality of conductive regions 150 of substrate 100 by way of a plurality of wire bonds 70. By way of wire bonds 70, conductive regions 150, and network 115, chip 50 provides drive signals to conductive regions 120D-120F, which in turn are coupled to the conductive regions G of transistor dice 20D-20F. Since these transistors are typically coupled to the low side of the switching potential, chip 50 is often called a low-side driver chip. Chip 50 may be implemented by a die having three instances of the Low-Side Gate Driver model FAN 3100C or 3100T sold by Fairchild Semiconductor Corporation, the product datasheet of which is hereby incorporated by reference.

Each of high-side drive chips 60A-60C is attached to first surface 101 of substrate 100 and is coupled to a plurality of conductive regions 160 of substrate 100 by way of a plurality of wire bonds 70. By way of wire bonds 70, conductive regions 160, and network 115, chips 60A-60C provide drive signals to conductive regions 120A-120C, respectively, which in turn are coupled to the conductive regions G of transistor dice 20A-20C, respectively. Since these transistors are typically coupled to the high side of the switching potential, chips 60A-60C are often called high-side driver chips. Each chip 60A-60C may be implemented by the die provided in a High-Side Gate Driver model FAN7361 or FAN7362 sold by Fairchild Semiconductor Corporation, the product datasheet of which is hereby incorporated by reference.

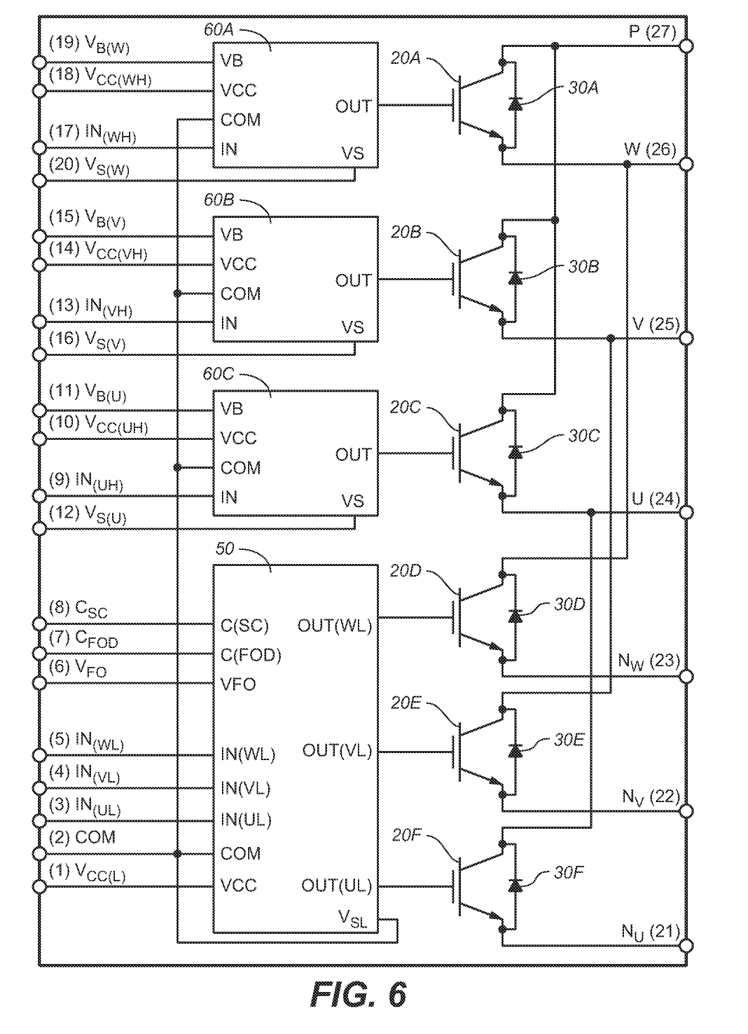

Referring to FIG. 5, semiconductor die package 10 preferably further comprises a body 80 of electrically insulating material disposed around substrates 100 and 200, and components 20A-20F, 30A-30F, 40C-40F, 50, arid 60A-60C. Body 80 preferably leaves the second surfaces 102, 202 of substrates 100, 200 exposed so that electrical contact may be made to lands 110 and conductive region 220. Body 80 provides mechanical support and electrical insulation for package 10. Package 10 has a leadless configuration, which means that there are no conductive leads extending substantially beyond the dimensions of the package. However, if desired, package 10 may be constructed to have leads. An exemplary implementation of package 10 has a length of 20.5 mm, a width of 18 mm, and a thickness of 2 mm. These dimensions are less than one-third the dimensions of DIP packages housing the same components, and represents at least a 65% reduction in the dimensions of the package.

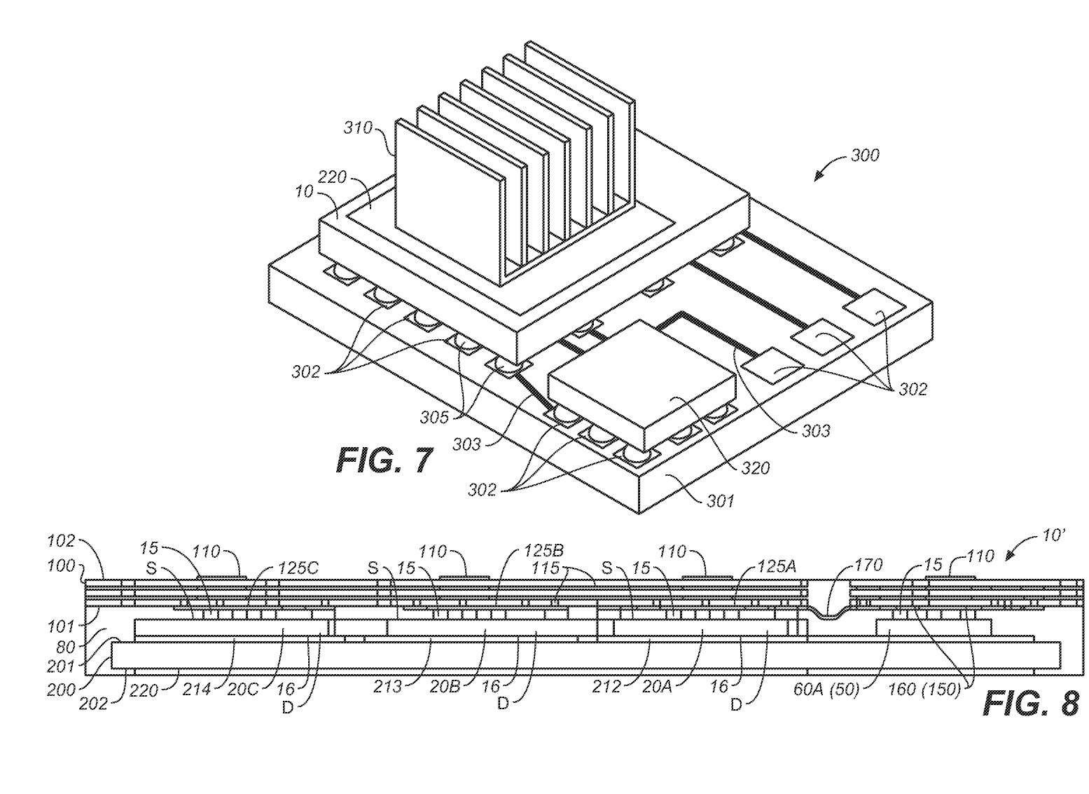

FIG. 7 shows a perspective view of a system 300 that comprises semiconductor package 10 according to the present invention. System 300 comprises an interconnect substrate 301, a plurality of interconnect pads 302 to which components are attached, a plurality of interconnect traces 303 (only a few of which are shown for the sake of visual clarity), an instance of package 10, a second package 320, and a plurality of solder bumps 305 that interconnect the packages to the interconnect pads 302. A heat sink 310 may be attached to conductive region 220 of package 10, such as by solder, thermally conductive adhesive, or thermally conductive grease.

FIG. 8 shows a side view of a second exemplary semiconductor die package 10′ according to the present invention. Package 10′ comprises the same components as package 10 configured in the same way except for the following differences: (1) IC chips 50 and 60 are flip-chip bonded to a plurality of conductive regions 150 and 160, respectively, of first substrate 100; (2) second substrate 200 extends further along the length of first substrate 100 so as to shield and attach to IC chips 50 and 60; (3) the portion of first substrate 100 having IC chips 50 and 60 is separated from the portion having components 20-40 but is electrically coupled thereto by a flexible circuit 170; and (4) the back surfaces of IC chips 50 and 60 are attached to first surface 201 of second substrate 200. These differences enable IC chips 50 and 60 to be flip-chip bonded to first substrate 100, and to have their back surfaces attached to second substrate 200 for heat removal. Flexible circuit 170 enables package 10′ to accommodate differences in thicknesses between IC chips 50 and 60 on the one hand, and components 20-40 on the other hand.

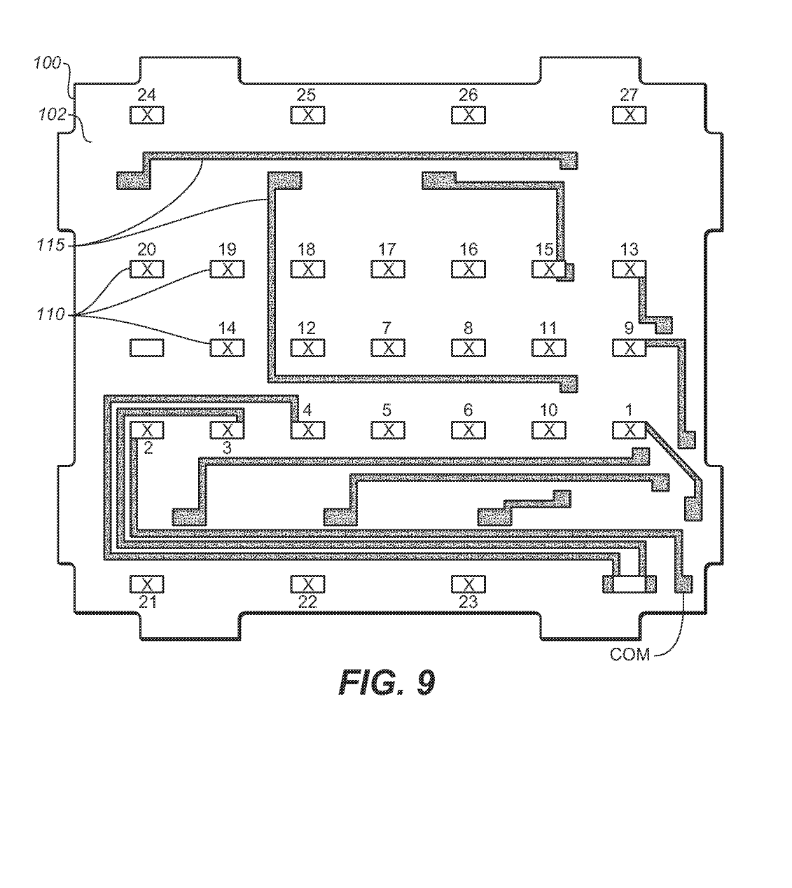

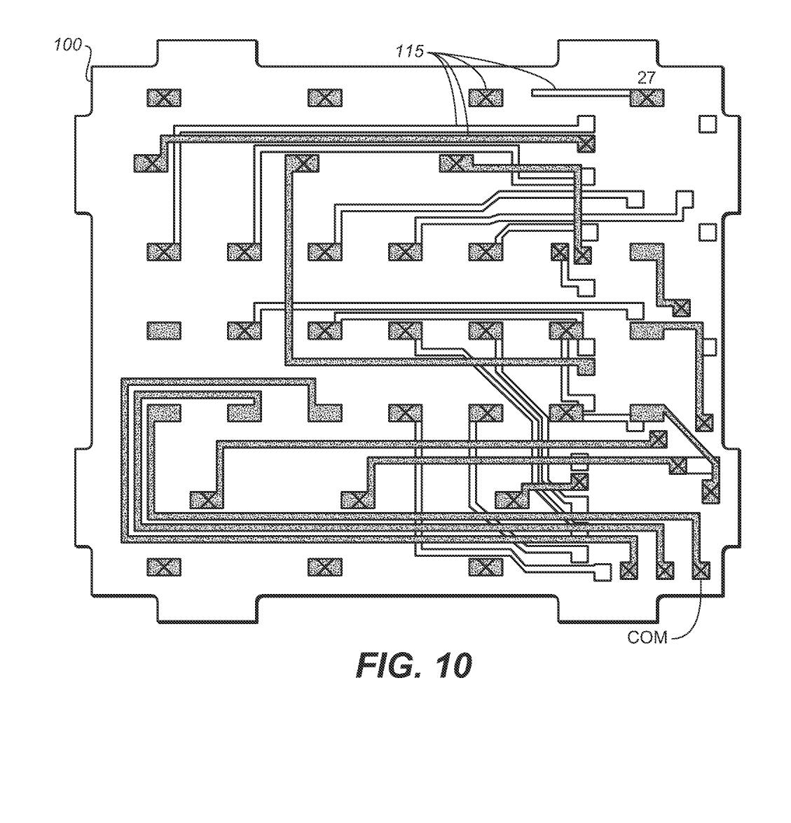

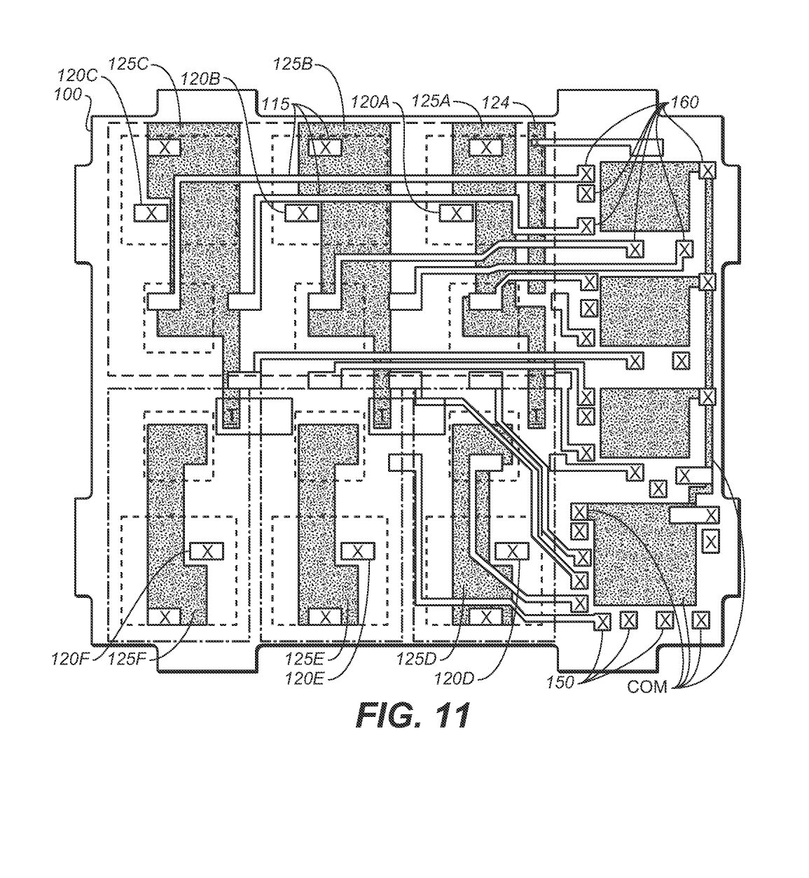

As indicated above, first substrate 100 may comprise a multi-layer printed circuit board with laminated substrate FR4 or ceramic substrate. For completeness, we show the traces and vias of the layers of an exemplary implementation in FIGS. 9-11. In the example, four metal layers are used. FIG. 9 shows the fourth metal layer in white, which provides lands 110 on the second surface 102 of substrate 100. The circuit pin numbers from the schematic diagram of FIG. 6 have been notated next to each land except two (which are not used). The third metal layer is shown in grey tone, with traces being the long thin structures, and with vias being within rectangular boxes and marked by “X” symbols. The vias shown in FIG. 9 are vias between the third and fourth layers. The top three traces provide electrical interconnections between high-side driver IC chips 60A-60C and the conduction regions G of semiconductor dice 20A-20C, respectively. The middle three lengthwise traces provide electrical interconnections between low-side driver IC chip 50 and the conduction regions G of semiconductor dice 20D-20F. The bottom three lengthwise traces provide electrical interconnections between low-side driver IC chip 50 and some of lands 110. FIG. 10 shows the third metal layer in a dark grey tone, and the traces of the second metal layer in white. Again, the traces are the long thin structures, and the vias are within rectangular boxes and marked by “X” symbols. The vias shown in FIG. 10 are vias between the third and second layers. The second metal layer provides electrical interconnections between IC chips 50 and 60A-60C on the one hand, and lands 110 on the other hand. FIG. 11 shows the second metal layer in white, and the first metal layer (which is disposed on first surface 101) in grey tone. The first layer provides the previously-described conductive regions 120A-120F, 124, 125A-125F, 150, 160. The vias shower in FIG. 11 are vias between the first and second metal layers are marked by “X” symbols. The positions of dice 20A-20F and 30A-30F and the conductive regions 211-214 of second substrate 200 are outlined. The interconnections between the COM pin 2 (FIG. 6) and dice 50 and 60A-60C are completed through die 50 and two wirebonds to die 50 in this example layout.

Exemplary methods of manufacturing packages 10 and 10′ are now described. Exemplary methods preferably comprise the following actions:
(A) assembling IC chips 50 and 60A-60C onto first substrate 100 and electrically coupling them to conductive regions 150 and 160, respectively, using wire bonds 70 or flip-chip bonds;
(B) assembling each of semiconductor dice 20A-20F onto either one of substrates 100 and 200, with its conductive regions facing respective conductive regions of the substrate, and with conductive adhesive material disposed between the facing conductive regions;
(C) assembling each of semiconductor dice 30A-30F onto either one of substrates 100 and 200, with its conductive regions facing respective conductive regions of the substrate, and with conductive adhesive material disposed between the facing conductive regions; this action may be omitted if semiconductor dice 20A-20F comprise integrated diodes;
(D) assembling each of conductive members 40C-40F onto either one of substrates 100 and 200, with its conductive regions facing respective conductive regions of the substrate, and with conductive adhesive material disposed between the facing conductive regions;
(E) assembling first substrate 100 and second substrate 200 together at their first surfaces 101 and 201, with semiconductor dice 20A-20F, 30A-30F and conductive members 40C-40F being disposed between the first surfaces of the substrates, with the previously unattached conductive regions of semiconductor dice 20A-20F, 30A-30F and conductive members 40C-40F being assembled to face respective conductive regions of a substrate with conductive adhesive disposed therebetween;
(F) when the conductive adhesive comprises solder paste material, reflowing the solder paste material, such as exposing the assembled package to an elevated temperature (e.g., by applying heat); and
(G) as an optional action, disposing molding material 80 about the sides of packages 100 and 200 and at least a portion of the gap between the substrates to form a housing.

Since the performance of actions (A) through (D) are not predicated on the completion of any action, they may be performed in any time sequence (e.g., time order) with respect to one another, including interleaved sequences of various actions (A)-(D) or all of said actions, and including simultaneous performance of various actions (A)-(D) or all said actions. In addition, action (A) may also be performed after any of actions (E) and (F) for manufacturing package 10. In general, action (E) is typically performed after actions (B) through (D) have been performed. Action (F) is preferably performed after all actions (B)-(E) have been preformed, but may be performed with action (E) and one or more of actions (B)-(D), such as by reflowing after one or more of the assembly actions (B)-(D) have been performed. In addition, when using a non-volatile solder paste (e.g., a solder paste that does not emit gas upon reflow and does not require cleaning after reflow), action (F) may be performed simultaneously with action (G), or afterwards. Accordingly, it may be appreciated that, while the method claims of the present application recite respective sets of actions, the claims are not limited to the order of the actions listed in the claim language, but instead cover all of the above possible orderings, including simultaneous and interleaving performance of actions and other possible orderings not explicitly described above, unless otherwise specified by the claim language (such as by explicitly stating that one action proceeds or follows another action).

In actions (B) through (D), the semiconductor dice 20-30 and the conductive members 40 may be assembled onto the same substrate or different substrates, and may be assembled onto the substrate(s) in any time sequence, thereby enabling the manufacturing process to be carried out in the most efficient manner depending upon the capabilities of the assembly equipment. Components 20-40 may be assembled onto one or both assembly surfaces of two substrates using pick-and-place equipment. In action (E), the substrates may be joined together using assembly equipment that does not require high alignment precision. Such assembly equipment may, for example, comprise a simple jig that couples to one of the substrates, and provides an alignment aperture or alignment guides for the other substrate. The relatively large size of connection pads on semiconductor die enables this fast and low cost assembly method to be used.

The flexibility in the placement of components during the assembly steps and the order of performing actions permit the methods of the present invention to be adapted to the available assembly equipment for maximum manufacturing efficiency and minimum cost. As one exemplary implementation, in one assembly line, several instances of substrate 100 are provided in matrix form on a common substrate, solder paste is printed over the conductive regions 120A-120F, 124, and 125A-125F (and optionally over regions 150 and 160 if dice 50 and 60 are to be attached by flip-chip bonding), and components 20-60 are assembled onto the instances of first substrate 100 using pick-and-place equipment. The tacky nature of the solder paste keeps the components in place during subsequent actions. If dice 50 and 60 are not to be flip-chip bonded, they may be attached to instances of substrate 100 with an adhesive, such as epoxy. Before or after the components are assembled onto the instances of substrate 100, the instances of substrate 100 may be separated from the common substrate. In another assembly line, several instances of substrate 200 are constructed from a common DBC or IMS substrate (such as by pattern etching to define conductive regions 211-214 from a common metal layer), and solder paste is printed over the conductive regions 211-214. Before or after the printing of solder paste, the instances of substrate 200 may be separated from the common substrate. Then, in a third assembly line, instances of substrates 100 and 200 are assembled together using a jig at a first station of the third assembly line. Next, the assembled instances are sent to a reflow station to heat and reflow the solder paste material, then sent to a wire bonding station to place wire bonds 70, and thereafter sent to a molding station to disposed molding body 80. In a further embodiment, the assembled instances are then sent to a solder-bump state to dispose solder bumps 112 on lands 110 for ball-grid array implementations. In the third assembly line, especially when manufacturing package 10′, it is possible for the instances of substrates 100 and 200 to still be in matrix form (i.e., as part of the common substrates) during the joining and reflow stations, and may be separated from the common substrates after the reflow step with sawing equipment at a sawing station. This is also possible when manufacturing package 10, provided that there is sufficient clearance space between wire bonds 70 and substrate 200 (substrate 200 would overlap die 50 and 60 in this case).

As another exemplary implementation, in one assembly line, several instances of substrate 100 are provided in matrix form on a common substrate. Dice 50 and 60 are attached to instances of substrate 100 with an adhesive, such as epoxy, using pick-and-place equipment, and then sent to a wire bonding station to place wire bonds 70. Before or after the wire bonding action, the instances of substrate 100 may be separated from the common substrate. As an optional step in this assembly line, solder paste or solder flux may be printed over the conductive regions 120A-120F, 124, and 125A-125F. In a second assembly line, several instances of substrate 200 are constructed from a common DBC or IMS substrate (such as by pattern etching to define conductive regions 211-214 from a common metal layer), and solder paste is printed over the conductive regions 211-214. Before or after the printing of solder paste, the instances of substrate 200 may be separated from the common substrate. In an assembly station, components 20-40 are assembled onto the instances of second substrate 200 using pick-and-place equipment. The tacky nature of the solder paste keeps the components in place during subsequent actions. Then, in a third assembly line, instances of substrates 100 and 200 are assembled together using a jig at a first station of the third assembly line. Next, the assembled instances are sent to a reflow station to heat and reflow the solder paste material, and then sent to a molding station to dispose molding body 80. In a further embodiment, the assembled instances are then sent to a solder-bump state to dispose solder bumps 112 on lands 110. In the third assembly line, it is possible for the instances of substrates 100 and 200 to still be in matrix form (i.e., as part of the common substrates) during the joining and reflow stations, and they may be separated from the common substrates after the reflow step with sawing equipment at a sawing station. This is possible provided that there is sufficient clearance space between wire bonds 70 and substrate 200 (substrate 200 would overlap die 50 and 60 in this case).

The semiconductor die packages described above can be used in electrical assemblies including circuit boards with the packages mounted thereon. They may also be used in systems such as phones, computers, etc.

Some of the examples described above are directed to “leadless” type packages such as MLP-type packages (microleadframe packages) where the terminal ends of the leads do not extend past the lateral edges of the molding material. Embodiments of the invention may also include leaded packages where the leads extend past the lateral surfaces of the molding material.

Any recitation of “a”, “an”, and “the” is intended to mean one or more unless specifically indicated to the contrary.

The terms and expressions which have been employed herein are used as terms of description and not of limitation, and there is no intention in the use of such terms and expressions of excluding equivalents of the features shown and described, it being recognized that various modifications are possible within the scope of the invention claimed.

Moreover, one or more features of one or more embodiments of the invention may be combined with one or more features of other embodiments of the invention without departing from the scope of the invention.

While the present invention has been particularly described with respect to the illustrated embodiments, it will be appreciated that various alterations, modifications, adaptations, and equivalent arrangements may be made based on the present disclosure, and are intended to be within the scope of the invention and the appended claims.

What is claimed is:

1. A semiconductor die package comprising:
a first substrate having a first surface, a second surface, a first electrically conductive region disposed on the first surface of the first substrate, and a second electrically conductive region disposed on the first surface of the first substrate;
a second substrate having a first surface, a second surface, and a first electrically conductive region disposed on the first surface of the second substrate;
a first semiconductor die disposed between the first surface of the first substrate and the first surface of the second substrate, the first semiconductor die having a first surface, a second surface, a first electrically conductive region at its first surface and electrically coupled to the first conductive region of the first substrate by a first body of conductive adhesive, and a second electrically conductive region at its second surface and electrically coupled to the first conductive region of the second substrate by a second body of conductive adhesive; and
a first electrically conductive member disposed between the first surface of the first substrate and the first surface of the second substrate, the first member having a first electrically conductive region electrically coupled to the second conductive region of the first substrate with a third body of conductive adhesive, a second electrically conductive region electrically coupled to the first conductive region of the second substrate with a fourth body of conductive adhesive.

2. The semiconductor die package of claim 1 wherein the first substrate further comprises a printed circuit board.

3. The semiconductor die package of claim 1 wherein the first substrate further comprises a plurality of conductive lands disposed on the second surface of the first substrate and a network of at least one electrical trace and one vertical connector, at least one of the conductive lands being electrically coupled to one of the first and second conductive regions of the first substrate.

4. The semiconductor die package of claim 1 wherein the second substrate comprises a direct-bonded-copper substrate having copper layers disposed on its first and second surfaces.

5. The semiconductor die package of claim 1 wherein the second substrate comprises a direct-bonded-copper substrate or an insulated metal substrate.

6. The semiconductor die package of claim 1 wherein the first semiconductor die comprises a vertical transistor device.

7. The semiconductor die package of claim 1 further comprising a second semiconductor die disposed between the first surface of the first substrate and the first surface of the second substrate, the second semiconductor die having a first surface, a second surface, a first electrically conductive region at its first surface and electrically coupled to the first conductive region of the first substrate by a fifth body of conductive adhesive, and a second electrically conductive region at its second surface electrically coupled to the first conductive region of the second substrate by a sixth body of conductive adhesive.

8. The semiconductor die package of claim 7 wherein the second semiconductor die comprises a vertical rectifier device.

9. The semiconductor die package of claim 1 wherein the first substrate further has a third conductive region disposed on its first surface, wherein the first semiconductor die further has a third electrically conductive region at the first surface of the first semiconductor die, the third conductive region being electrically coupled to the third conductive region of the first substrate by a body of conductive adhesive.

10. The semiconductor die package of claim 9 further comprising a second semiconductor die mounted to the first substrate and having an electrically conductive region electrically coupled to an electrical trace of the first substrate, wherein the electrical trace is electrically coupled to the third conductive region of the first semiconductor device.

11. The semiconductor die package of claim 1 further comprising a second semiconductor die mounted to the first substrate and having an electrically conductive region electrically coupled to an electrical trace of the first substrate, wherein the electrical trace is electrically coupled to a conductive region of the first semiconductor device.

12. A system comprising a substrate and the semiconductor die package of claim 1 attached to the substrate.

13. A method comprising:
assembling a first semiconductor die onto one of a first substrate and a second substrate, each substrate having a first surface, a second surface, and a conductive region disposed on its first surface, the semiconductor die having a first surface, a second surface, a first conductive region disposed on its first surface, and a second conductive region disposed on its second surface, the first semiconductor die being assembled onto the first surface of one of the substrates with one of its conductive regions facing the conductive region of the substrate, and with conductive adhesive material disposed between the facing conductive regions;
assembling a first conductive member onto one of the first and second substrates, the conductive member having a first conductive surface and a second conductive surface, the first conductive member being assembled onto the first surface of one of the substrates with one of its conductive regions facing the conductive region of the substrate, and with conductive adhesive material disposed between the facing conductive regions; and
assembling the first and second substrates together at their first surfaces with the first semiconductor die and the first conductive member being disposed between the first surfaces of the substrates, with the other conductive region of the first semiconductor die facing a conductive region of a substrate with conductive adhesive material disposed between the facing conductive regions, and with the other conductive region of the first conductive member facing a conductive region of a substrate with conductive adhesive material disposed between the facing conductive regions.

14. The method of claim 13 wherein the conductive adhesive material comprises solder material, and wherein the method further comprises reflowing the solder material.

15. The method of claim 13 further comprising disposing molding material around the sides of the first and second substrates and between at least a portion of the gap between the substrates.

16. The method of claim 13 wherein the first substrate comprises at least one of a printed-circuit board, a multi-layer printed-circuit board with a laminated FR4 substrate, or a multi-layer ceramic substrate, and wherein the second substrate comprises at least one of a direct-bonded copper substrate or an insulated metal substrate.

17. The method of claim 13 wherein the first substrate further has a second conductive region disposed on its first surface, and wherein the first semiconductor die and the first conductive member have conductive regions electrically coupled to different conductive regions on the first surface of the first substrate.

18. The method of claim 17 wherein assembling the first semiconductor die onto one of the first and second substrates comprises assembling the first semiconductor die onto the first substrate.

19. The method of claim 18 wherein assembling the first conductive member onto one of the first and second substrates comprises assembling the first conductive member onto the first substrate.

20. The method of claim 18 wherein assembling the first conductive member onto one of the first and second substrates comprises assembling the first conductive member onto the second substrate.

21. The method of claim 17 wherein assembling the first semiconductor die onto one of the first and second substrates comprises assembling the first semiconductor die onto the second substrate.

22. The method of claim 21 wherein assembling the first conductive member onto one of the first and second substrates comprises assembling the first conductive member onto the first substrate.

23. The method of claim 21 wherein assembling the first conductive member onto one of the first and second substrates comprises assembling the first conductive member onto the second substrate.

24. The method of claim 13 further comprising mounting an IC chip to the first surface of the first substrate and attaching a plurality of conductive structures between the IC chip and a plurality of additional conductive regions on the first surface of the first substrate.

25. The method of claim 13 further comprising flip-chip bonding an IC chip to a plurality of additional conductive regions on the first surface of the first substrate.
